(19) United States
(12) Patent Application Publication
(10) Pub. No.: US 2007/0176254 A1
(43) Pub. Date: Aug. 2, 2007

(54) Poly emitter bipolar device configuration and fabrication method with an inter-level dielectric deposited by plasma enhanced chemical vapor deposition

(75) Inventors: Xian-Feng Liu, Shanghai (CN); Chong Ren, Shanghai (CN); Jin-Chuan Zeng, Shanghai (CN); Bin Qiu, Shanghai (CN)

Correspondence Address: BIRCH STEWART KOLASCH & BIRCH, PO BOX 747, FALLS CHURCH, VA, 22040-0747, US

(73) Assignee: BCD Semiconductor Manufacturing Limited

(21) Appl. No.: 11/341,493

(22) Filed: Jan. 30, 2006

(51) Int. Cl. H01L 29/00

(52) U.S. Cl. 257/511; 438/328; 257/370; 257/E27.017

(57) ABSTRACT

The present invention discloses a high voltage and high frequency poly emitter bipolar structure with improved breakdown voltage performance. The advantage of the poly emitter bipolar structures is that the SOD coating layer can improve the breakdown voltage of a capacitor structure higher to be 6-8 volts. In addition, the poly emitter bipolar structure having the inter-level dielectric layer deposited by PECVD on the emitter and collector by optimizing PECVD deposition process condition to adjust the charge in the oxide of inter-level dielectric layer has a breakdown voltage higher than 30 volts.

### FIELD OF THE INVENTION

The present invention generally relates to the field of high voltage and high frequency poly emitter bipolar structures, and particularly to a processing method for improving the breakdown voltage (BVcbo) of oxide between the emitter and collector of a poly emitter bipolar structure with an inter-level dielectric (ILD) layer deposited by plasma enhanced chemical vapor deposition (PECVD).

### BACKGROUND OF THE INVENTION

The poly-silicon emitter bipolar has high frequency performance and been used extensively in high frequency low voltage system. Because the poly-silicon emitter bipolar with high frequency performance needs the shallow junction depth and the poly-silicon emitter bipolar with high voltage performance needs deep junction, there is tradeoff between voltage and frequency in high voltage and high frequency poly-silicon emitter bipolar process. In general, some solutions to this problem are found in the silicon semiconductor industry. Choosing high resistivity and thick epitaxy or diffused guard ring, floating guard ring and field plate technique are used to improve breakdown voltage with shallow base junction depth. However, the above methods increase the area of the devices or degrade the performance of the devices.

Referring to FIG. 1, it shows a cross section of a conventional bipolar junction transistor (BJT) with NPN type. The inter-level dielectric (ILD) layer 160 in conventional bipolar structures 10 is deposited by low pressure chemical vapor deposition (LPCVD) or low temperature CVD using Tetraethyl Orthosilicate (TEOS) based materials. The breakdown voltage (BVcbo) of oxide between the emitter and collector of the conventional bipolar structures 10 is much lower than 10 volts. In addition, the metal deposited to contact the collector contact 120, and the base contact 130 and the emitter contact 140 is Pt alloy only, which can not improve the performance of the Schottkey diode in the BJT structure.

U.S. Pat. No. 6,858,887 issued by Li , et al., entitled “BJT device configuration and fabrication method with reduced emitter width”, discloses a BJT device configuration including an emitter finger and the via arrangement which reduces emitter finger width, and is particularly suitable for use with compound semiconductor-based devices. Each emitter finger includes a cross-shaped metal contact which provides an emitter contact and each contact comprises two perpendicular arms which intersect at a central area. A via through an inter-level dielectric layer provides access to the emitter contact. The via is square-shaped, centered over the center point of the central area, and oriented at a 45 DEG angle to the arms. This allows the via size to be equal to or greater than the minimum process dimension, while allowing the width of the emitter finger to be as narrow as possible with the alignment tolerances still being met. However, the disclosed devices based on compound semiconductors employed for operation at very high frequencies are not feasible, since the high temperature processing is required to fabricate the polycrystalline silicon emitter which is incompatible with the processes needed to fabricate compound semiconductors, and no convenient analog to polysilicon exists in compound semiconductors.

According to the above problems, there is a need to provide a processing method and configuration for improving breakdown voltage of a poly emitter bipolar structure.

### SUMMARY OF THE INVENTION

It is an objective of the present invention to provide a processing method of improving breakdown voltage (BVcbo) of a poly emitter bipolar structure with poly-silicon emitter and an ILD layer deposited by PECVD.

It is another objective of the present invention to provide a configuration of improving breakdown voltage of a poly emitter bipolar structure with poly-silicon emitter and an ILD layer deposited by PECVD.

To achieve the above and other objectives, the present invention provides a poly emitter bipolar structure with improved breakdown voltage performance. It comprises a semi-insulating substrate; a collector formed on the substrate; a base formed on the collector; an emitter formed on the base; a first metal contact on the collector which provides a collector contact for the poly emitter bipolar structures; a second metal contact on the emitter which provides an emitter contact for the poly emitter bipolar structures; an inter-level dielectric layer deposited by PECVD on the emitter and collector by optimizing PECVD deposition process condition to adjust the charge in the oxide; three via holes through the inter-level dielectric layer which provides access to the collector contact, a base contact and the emitter contact; and a fourth metal deposited to contact the collector contact, the base contact and the emitter contact to be a collector electrode, a base electrode and an emitter electrode of the poly emitter bipolar structures.

According to one aspect of the poly emitter bipolar structures of the present invention, the first metal contact and the second metal contact are formed by polysilicon doped with phosphide ion.

According to the preferred embodiment of the present invention, the breakdown voltage (BVcbo) of oxide between the emitter and collector can be improved from 30V to 45V without changing epitaxy layer thickness, resistivity, and therefore without affecting other device performance.

The present invention also provides a method for fabricating a poly emitter bipolar structure with improved breakdown voltage performance. It comprises the steps of providing a semi-insulating substrate; forming a collector on the substrate; forming a base on the collector; forming an emitter on the base; providing a first metal contact on the collector which provides a collector contact for the poly emitter bipolar structures; providing a second metal contact on the emitter which provides an emitter contact for the poly emitter bipolar structures; depositing an inter-level dielectric layer (ILD) by PECVD on the emitter and collector by optimizing PECVD deposition process condition to adjust the charge in the oxide of inter-level dielectric layer; forming three via holes through the inter-level dielectric layer which provides access to the collector contact, a base contact and the emitter contact; and depositing a fourth metal to contact the collector contact, the base contact and the emitter contact to be a collector electrode, a base electrode and a emitter electrode of the poly emitter bipolar structures.

The advantage of the poly emitter bipolar structures of the present invention is that to change the field deposition SiO₂ with PECVD deposition SiO₂ instead of traditional LPCVD or LTO SiO₂ by optimizing PECVD deposition process condition to adjust the charge in the oxide to meet the device breakdown voltage requirement, the breakdown voltage (BVcbo) of oxide between the emitter and collector can be improved from 30V to 45V without changing epitaxy layer thickness, resistivity, and therefore without affecting other device performance.

The another advantage of the poly emitter bipolar structures of the present invention is that this invention integrate high unit capacitance diode ISO/BN with low breakdown voltage between 6˜8V, high voltage MIS capacitor with poly-silicon as upper plate and Xbase or N+ as lower plate and low forward voltage Schottky diode with PtSi/TiW/AlSiCu.

### BRIEF DESCRIPTION OF THE DRAWINGS

All the objects, advantages, and novel features of the present invention will become more apparent from the following detailed descriptions when taken in conjunction with the accompanying drawings.

FIG. 1 shows a cross section of a conventional poly emitter bipolar structure with NPN type;

FIG. 2 shows a cross section of a poly emitter bipolar structure with NPN type according to the embodiment of the present invention;

FIGS. 3A to 3J show processing flows of providing a semi-insulating substrate of the poly emitter bipolar structures in FIG. 2 according to the embodiment of the present invention;

FIGS. 4A to 4C show processing flows of forming a collector on the substrate of the poly emitter bipolar structures in FIG. 2 according to the embodiment of the present invention;

FIGS. 5A to 5C show processing flows of forming a base on the collector in FIG. 2 according to the embodiment of the present invention;

FIGS. 6A to 6C show processing flows of forming an emitter on the base in FIG. 2 according to the embodiment of the present invention;

FIGS. 7A and 7B show processing flows of providing first and second metal contacts of the BJT in FIG. 2 according to the embodiment of the present invention;

FIGS. 8A and 8B show processing flows of depositing an inter-level dielectric layer by PECVD on the emitter and collector of the poly emitter bipolar structures in FIG. 2 according to the embodiment of the present invention;

FIGS. 9A to 9E show processing flows of forming three via holes through the inter-level dielectric layer of the poly emitter bipolar structures in FIG. 2 according to the embodiment of the present invention; and

FIG. 10 shows processing flows of depositing a fourth metal of the poly emitter bipolar structures in FIG. 2 according to the embodiment of the present invention.

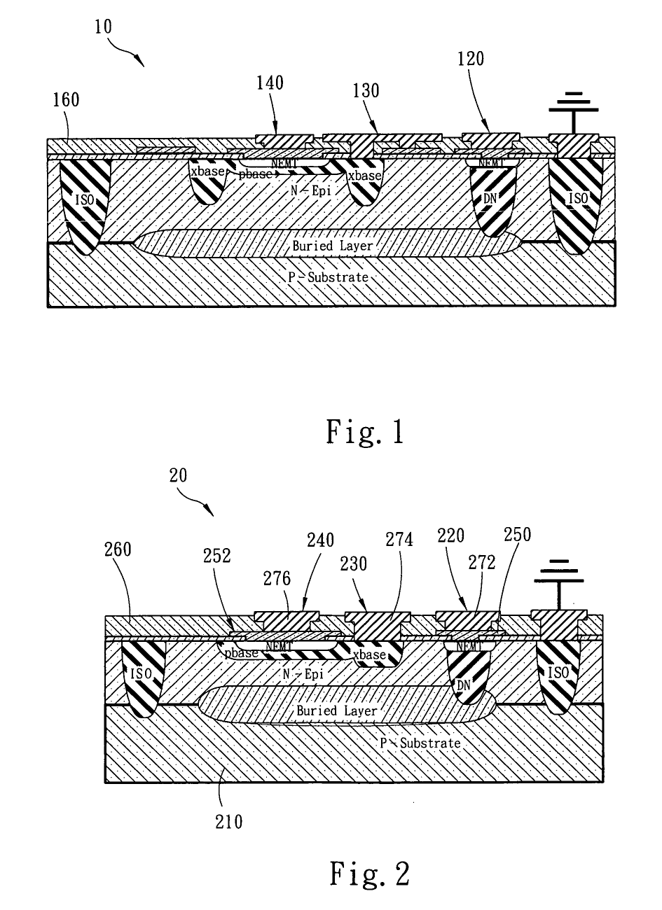

### DETAILED DESCRIPTION OF THE PREFERRED EMBODIMENTS

Although the present invention has been explained in relation to several preferred embodiments, the accompanying drawings and the following detailed descriptions are the preferred embodiment of the present invention. It is to be understood that the following disclosed descriptions will be examples of the present invention, and will not limit the present invention into the drawings and the special embodiment.

Referring to FIG. 2, it shows a cross section of a poly emitter bipolar structure 20 with NPN type according to the embodiment of the present invention. A poly emitter bipolar structures 20 comprises a semi-insulating substrate 210; a collector 220 formed on the substrate 210; a base 230 formed on the collector 220; an emitter 240 formed on the base 230; a first metal contact 250 on the collector 220 which provides a collector contact for the poly emitter bipolar structures 20; a second metal contact 252 on the emitter 240 which provides an emitter contact for the poly emitter bipolar structures 20; an inter-level dielectric layer (ILD) 260 deposited by PECVD on the emitter 240 and the collector 220 by optimizing PECVD deposition process condition to adjust the charge in the oxide of inter-level dielectric layer; three via holes through the inter-level dielectric layer 260 which provides access to the collector contact, a base contact and the emitter contact; and a fourth metal deposited to contact the collector contact, the base contact and the emitter contact to be a collector electrode 272, a base electrode 274 and a emitter electrode 276 of the BJT 20. The semi-insulating substrate comprises silicon, silicon-on-insulator (SOI), silicon-germanium (SiGe), gallium arsenide (GaAs), indium phosphide (InP) and silicon-germanium-carbon (SiGe—C). The first metal contact 250 and the second metal contact 252 are formed by polysilicon doped with phosphide ion. The semi-insulating substrate 210 has a SOD coating layer on its top, which the SOD coating layer can improve the breakdown voltage of a capacitor structure in the BJT structure higher to be 6-8 volts. The fourth metal deposited to contact the collector contact, the base contact and the emitter contact can be selected from the group of PtSi, TiW and AlSiCu, which can improve the performance of the Schottkey diode in the poly emitter bipolar structures. The ILD layer deposited by PECVD on the emitter 240 and the collector 220 has a breakdown voltage higher than 15 volts.

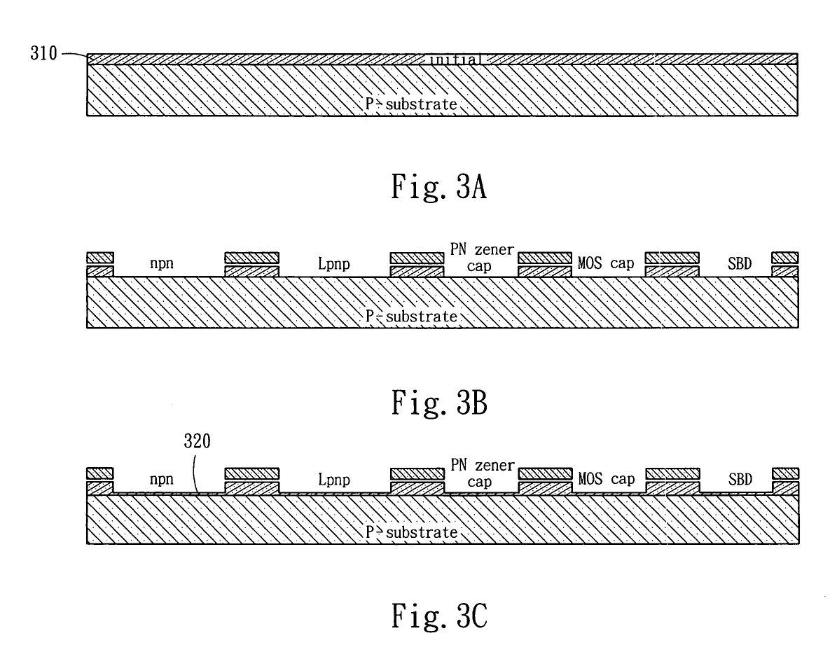

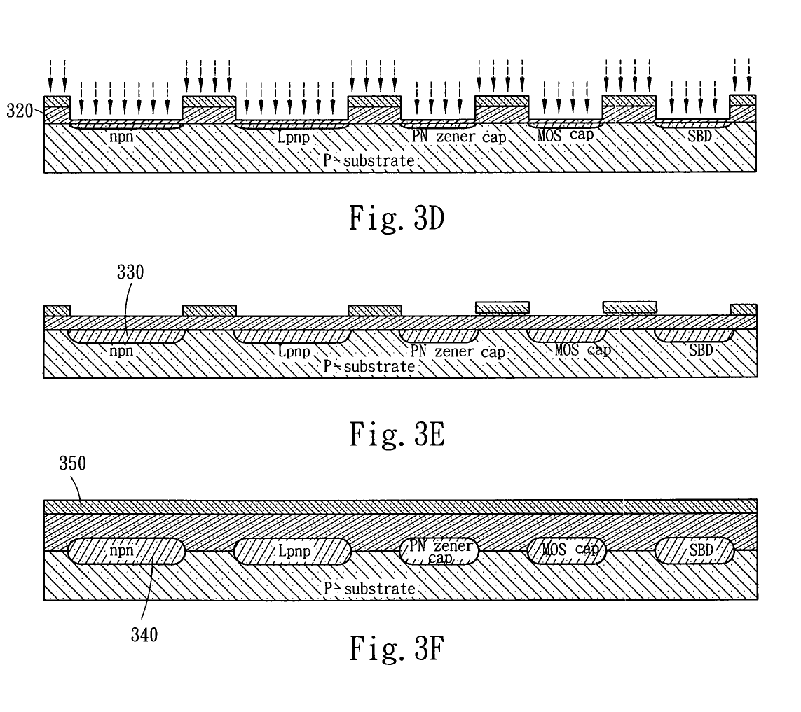

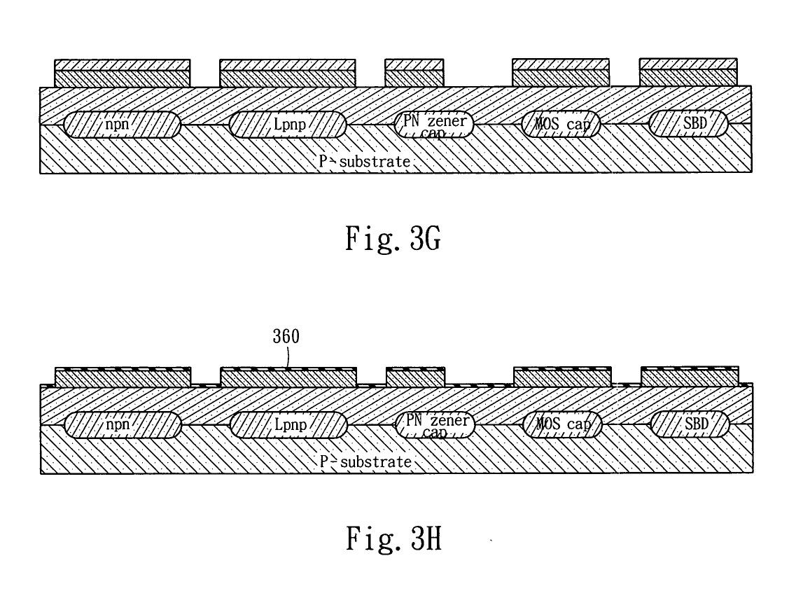

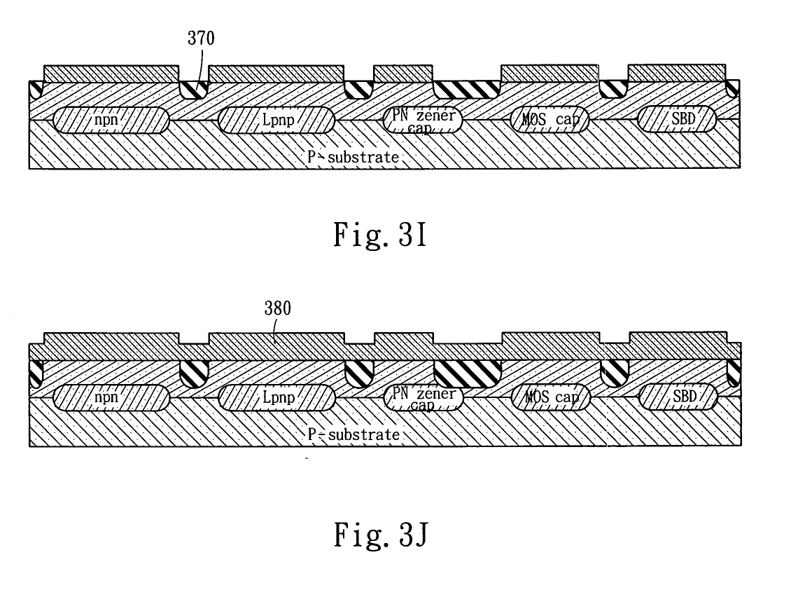

FIGS. 3A to 3J show processing flows of providing a semi-insulating substrate of the poly emitter bipolar structures in FIG. 2 according to the embodiment of the present invention. An initial oxidation 310 is formed, patterned, and etched. Then a pre-oxide 320 for ion implant is formed, and Sb ion is implanted and then driven in by annealing at suitable temperature to form a buried layer 330. Epitaxy 340 is formed, and then oxidation 350 is patterned. The spin on dielectric (SOD) 360 is coated and then etched to form the isolation (ISO) 370, followed by oxidation 380.

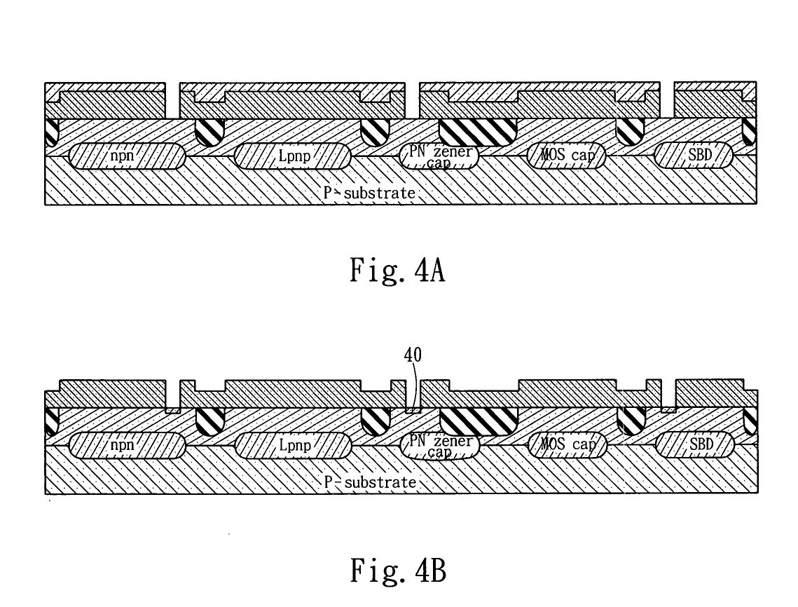

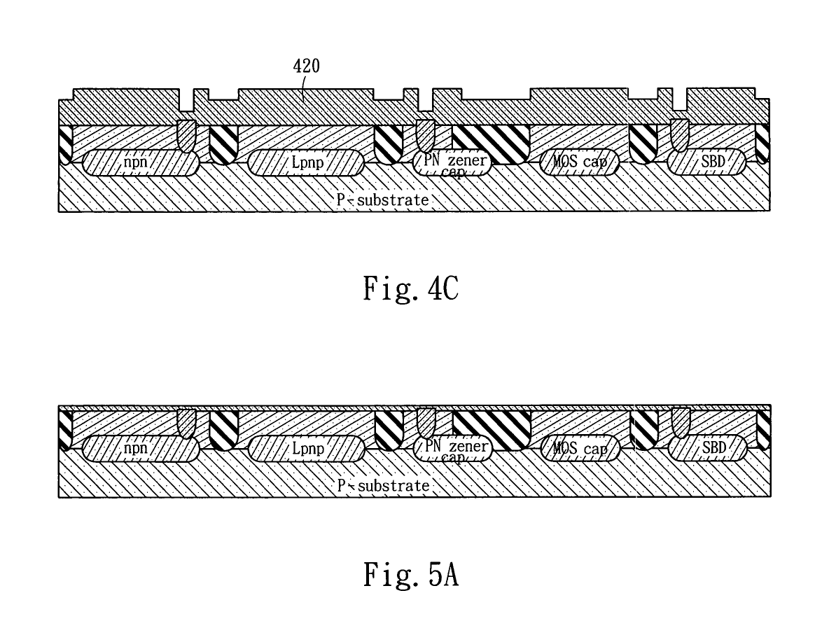

FIGS. 4A to 4C show processing flows of forming a collector on the substrate of the poly emitter bipolar structures in FIG. 2 according to the embodiment of the present invention. After oxidation 380 is patterned, PoCl₃ 410 is implanted and then driven in by annealing at suitable temperature, followed by oxidation 420.

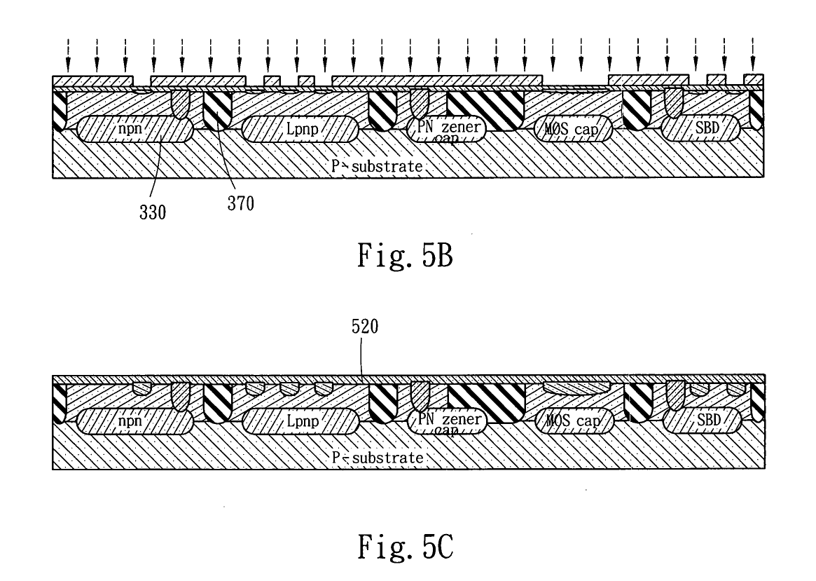

FIGS. 5A to 5C show processing flows of forming a base on the collector in FIG. 2 according to the embodiment of the present invention. After patterning the oxidation 420, the B⁺ ion is implanted and driven in to be emitter, followed by oxidation 520.

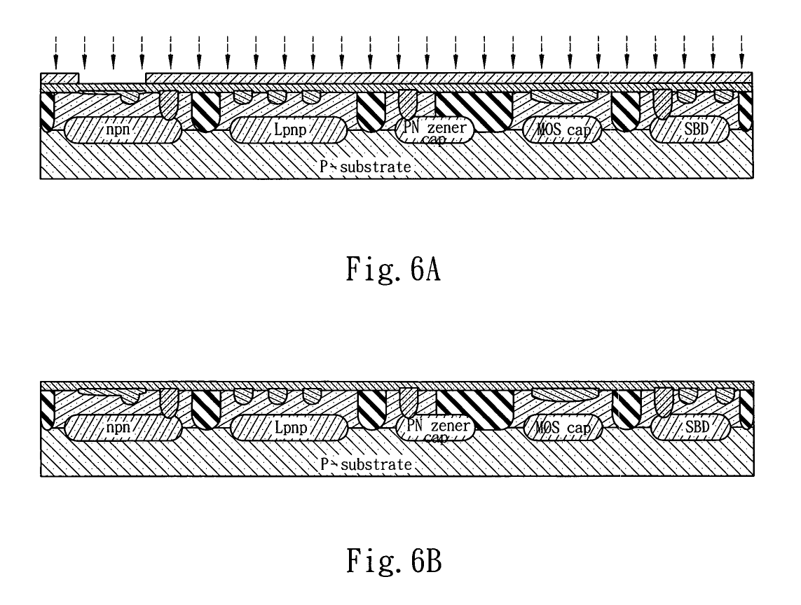

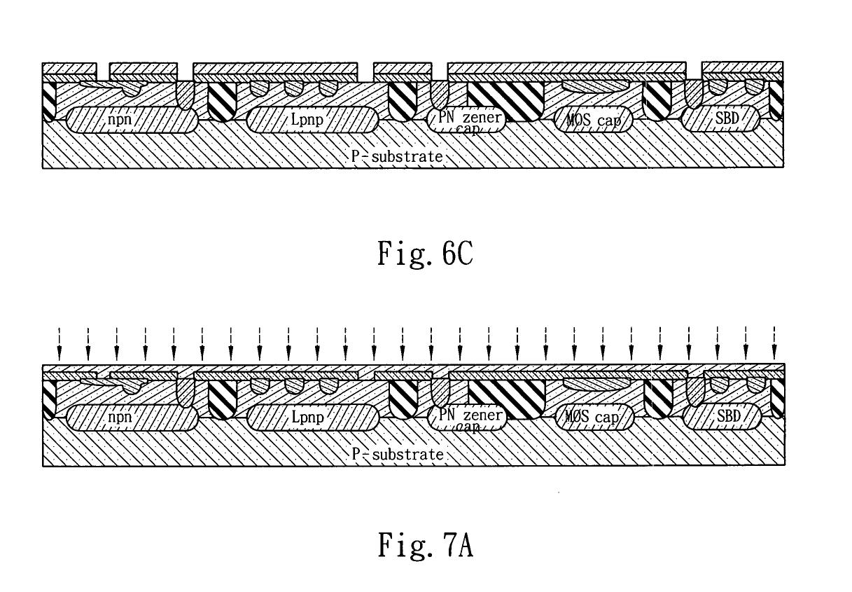

FIGS. 6A to 6C show processing flows of forming an emitter on the base in FIG. 2 according to the embodiment of the present invention. After patterning oxidation 520, the P⁺ ion is implanted and driven in to be base.

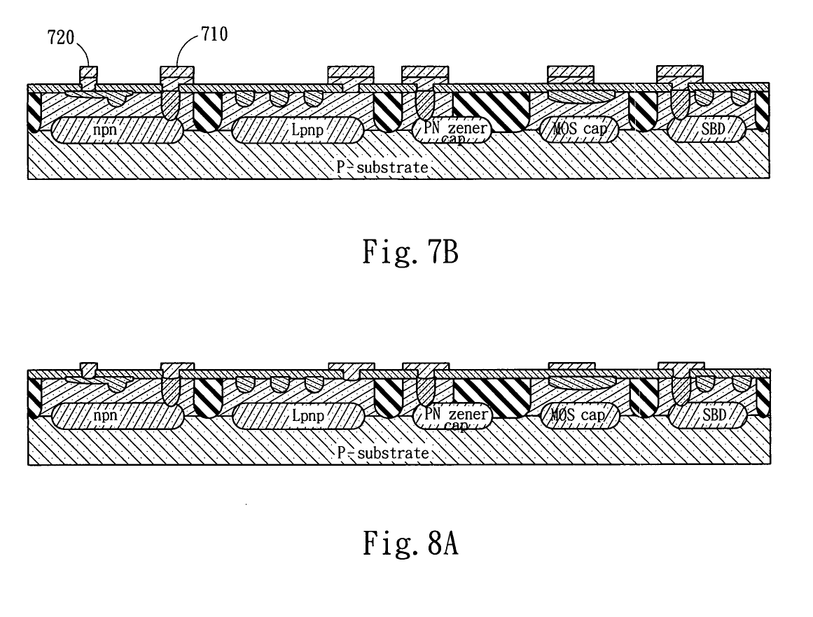

FIGS. 7A and 7B show processing flows of providing first and second metal contacts of the poly emitter bipolar structures in FIG. 2 according to the embodiment of the present invention. Polysilicon is deposited and P⁺ ion is implanted and then polysilicon is patterned to form a collector contact 710 and an emitter contact 720.

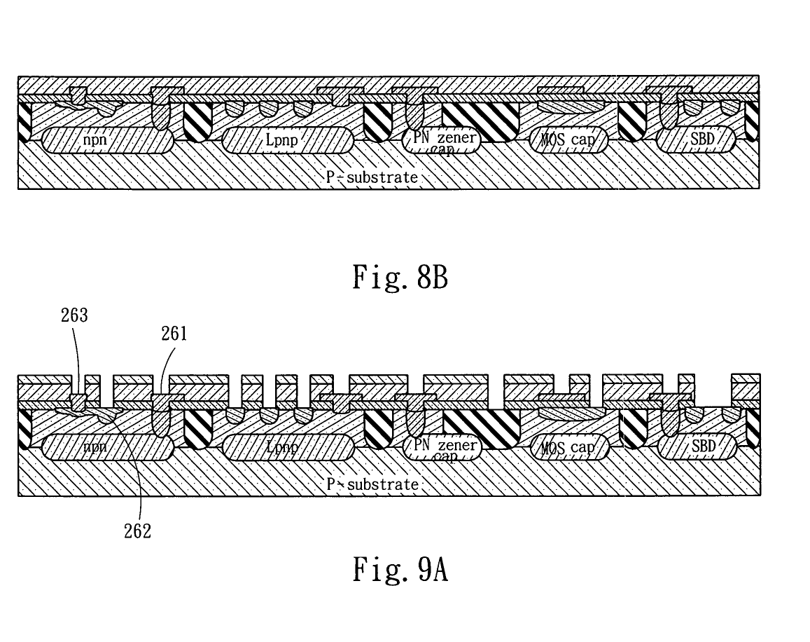

FIGS. 8A and 8B show processing flows of depositing an inter-level dielectric layer (ILD) 260 by PECVD on the emitter and collector of the poly emitter bipolar structures 20 in FIG. 2 according to the embodiment of the present invention. The inter-level dielectric layer (ILD) 260 covers the BJT structure. By optimizing PECVD deposition process condition such as substrate temperature, gas flow rate, working pressure and power to adjust the charge in the oxide of inter-level dielectric layer (ILD) to meet the device breakdown voltage requirement.

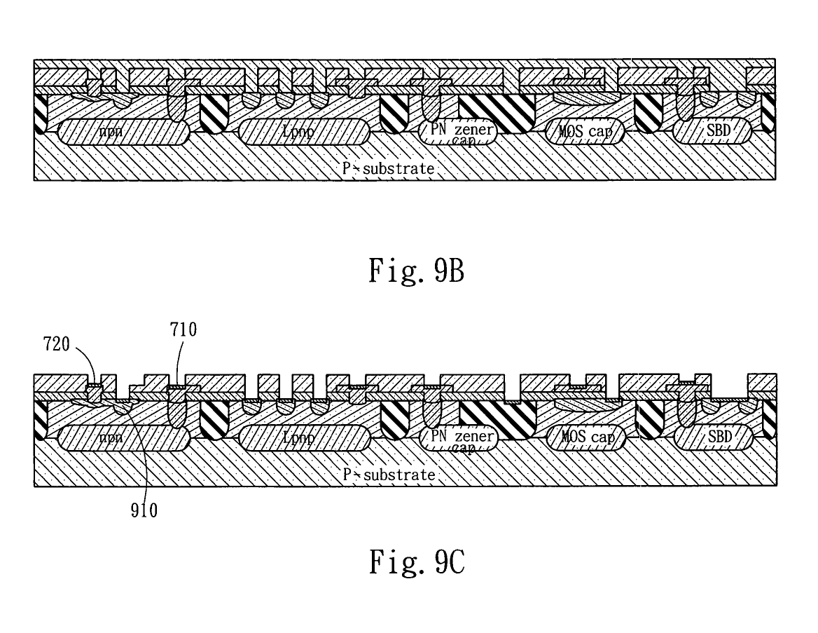

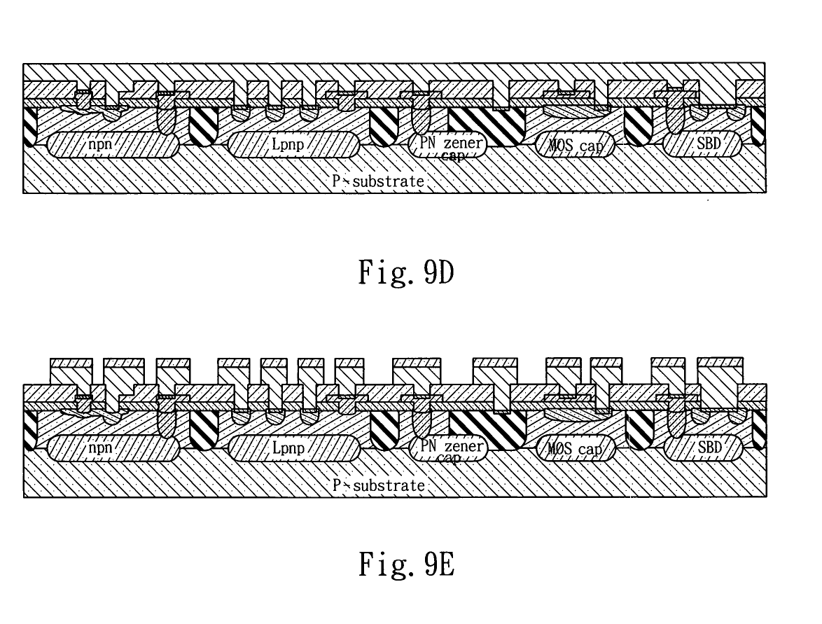

FIGS. 9A to 9E show processing flows of forming three via holes through the inter-level dielectric layer of the poly emitter bipolar structures in FIG. 2 according to the embodiment of the present invention. Vias 261 are formed through the inter-level dielectric layer 260 to access the device contacts. Vias 261 provide access to the collector contact 710, and a via 262 is formed to provide access to a base contact 910. Another via 263 is formed through the inter-level dielectric layer 260 to provide access to the emitter contact 720.

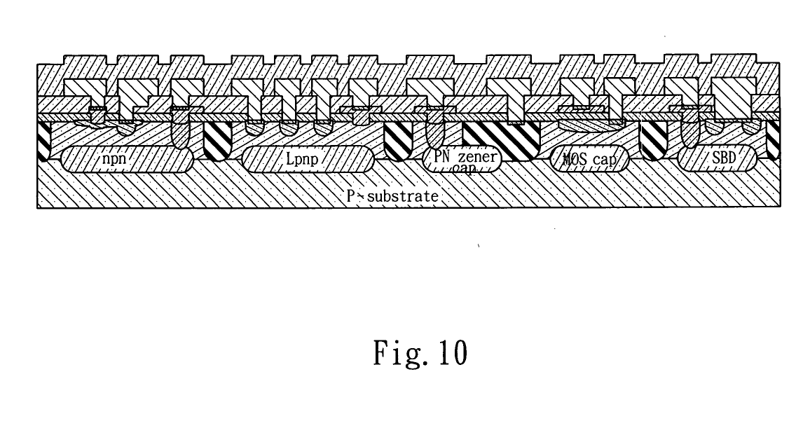

FIG. 10 shows processing flows of depositing a fourth metal of the poly emitter bipolar structures in FIG. 2 according to the embodiment of the present invention. Platinum is first deposited to form an alloy and then patterned. And TiW or AlSiCu is deposited and then patterned. After, a dielectric is deposited to form the passivation.

According to the preferred embodiment of the present invention, this invention provides one method to change the field deposition SiO₂ with PECVD deposition SiO₂ instead of traditional LPCVD or LTO SiO₂. By optimizing PECVD deposition process condition to adjust the charge in the oxide to meet the device breakdown voltage requirement, the breakdown voltage (BVcbo) of oxide between the emitter and collector can be improved from 30V to 45V without changing epitaxy layer thickness, resistivity, and therefore without affecting other device performance. So the saturation voltage and cut off frequency performance have been improved. Also this invention integrate high unit capacitance diode ISO/BN with low breakdown voltage between 6˜8V, high voltage MIS capacitor with poly-silicon as upper plate and Xbase or N+ as lower plate and low forward voltage Schottky diode with PtSi/TiW/AlSiCu.

The process sequence depicted in FIGS. 3A to 10 shows only one method of fabricating a device in accordance with the present invention. Many other processes might be employed to produce the BJT structure.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A poly emitter bipolar structures with improved breakdown voltage performance, comprising:
a semi-insulating substrate;
a collector formed on the substrate;
a base formed on the collector;
an emitter formed on the base;
a first metal contact on the collector which provides a collector contact for the poly emitter bipolar structures;
a second metal contact on the emitter which provides an emitter contact for the poly emitter bipolar structures;
an inter-level dielectric layer deposited by PECVD on the emitter and collector by optimizing PECVD deposition process condition to adjust the charge in the oxide of inter-level dielectric layer;
three via holes through the inter-level dielectric layer which provides access to the collector contact, a base contact and the emitter contact; and
a fourth metal deposited to contact the collector contact, the base contact and the emitter contact to be a collector electrode, a base electrode and a emitter electrode of the poly emitter bipolar structures.

2. The poly emitter bipolar structures of claim 1, wherein the semi-insulating substrate comprises silicon germanium (SiGe).

3. The poly emitter bipolar structures of claim 1, wherein the semi-insulating substrate is a compound semiconductor.

4. The poly emitter bipolar structures of claim 1, wherein the first metal contact and the second metal contact are formed by polysilicon doped with phosphide ion.

5. The poly emitter bipolar structures of claim 1, wherein the semi-insulating substrate has a spin on dielectric (SOD) coating layer on its top, and the SOD coating layer can improve the breakdown voltage of a capacitor structure in the poly emitter bipolar structures structure higher to be 6-8 volts.

6. The poly emitter bipolar structures of claim 1, wherein the fourth metal deposited to contact the collector contact, the base contact and the emitter contact can be selected from the group of PtSi, TiW, and AlSiCu, which can improve the performance of the Schottkey diode in the poly emitter bipolar structures.

7. The poly emitter bipolar structures of claim 1, wherein the poly emitter bipolar structures having the inter-level dielectric layer deposited by PECVD on the emitter and collector has a breakdown voltage higher than 30 volts.

8. A method for fabricating a poly emitter bipolar structure with improved breakdown voltage performance, comprising the steps of: providing a semi-insulating substrate;
forming a collector on the substrate;
forming a base on the collector;
forming an emitter on the base;
providing a first metal contact on the collector which provides a collector contact for the poly emitter bipolar structures;
providing a second metal contact on the emitter which provides an emitter contact for the poly emitter bipolar structures;
depositing an inter-level dielectric layer by PECVD on the emitter and collector by optimizing PECVD deposition process condition to adjust the charge in the oxide of inter-level dielectric layer;
forming three via holes through the inter-level dielectric layer which provides access to the collector contact, a base contact and the emitter contact; and
depositing a fourth metal to contact the collector contact, the base contact and the emitter contact to be a collector electrode, a base electrode and a emitter electrode of the poly emitter bipolar structures.

9. The method of claim 8, wherein the semi-insulating substrate comprises silicon germanium (SiGe).

10. The method of claim 8, wherein the semi-insulating substrate is a compound semiconductor.

11. The method of claim 8, wherein the first metal contact and the second metal contact are formed by polysilicon doped with phosphide ion.

12. The method of claim 8, wherein the semi-insulating substrate has a SOD coating layer on its top, and the SOD coating layer can improve the breakdown voltage of a capacitor structure in the poly emitter bipolar structures structure higher to be 6-8 volts.

13. The method of claim 8, wherein the fourth metal deposited to contact the collector contact, the base contact and the emitter contact can be selected from the group of PtSi, TiW, and AlSiCu, which can improve the performance of the Schottkey diode in the poly emitter bipolar structures.

14. The method of claim 8, wherein depositing the inter-level dielectric layer by PECVD on the emitter and collector can increase a breakdown voltage of the poly emitter bipolar structures to be higher than 15 volts.
